(19) United States
(12) Patent Application Publication
(10) Pub. No.: US 2023/0301078 A1
(43) Pub. Date: Sep. 21, 2023

(54) MEMORY DEVICE AND MANUFACTURING METHOD OF THE MEMORY DEVICE

(71) Applicant: SK hynix Inc., Icheon-si Gyeonggi-do (KR)

(72) Inventor: Yun Cheol HAN, Icheon-si Gyeonggi-do (KR)

(73) Assignee: SK hynix Inc., Icheon-si Gyeonggi-do (KR)

(21) Appl. No.: 17/884,043

(22) Filed: Aug. 9, 2022

(30) Foreign Application Priority Data
Mar. 17, 2022 (KR) 10-2022-0033632

(51) Int. Cl. H01L 27/11556; H01L 27/11519; H01L 27/11526

(52) U.S. Cl. CPC H01L 27/11556; H01L 27/11519; H01L 27/11526

(57) ABSTRACT

A memory device includes isolation layers and gate structures alternately stacked on a lower structure and a tunnel isolation layer penetrating the isolation layers and the gate structures. The memory device also includes a channel layer formed along an inner wall of the tunnel isolation layer and a core plug formed along an inner wall of the channel layer. Each of the gate structures includes: a floating gate surrounding an outer wall of the tunnel isolation layer; a first dielectric layer surrounding an outer wall of the floating gate; a second dielectric layer surrounding an outer wall of the first dielectric layer; a third dielectric layer surrounding an outer wall of the second dielectric layer; and a gate line formed between the isolation layers, the gate line filling a region surrounded at least in part by the third dielectric layer.

### CROSS-REFERENCE TO RELATED APPLICATION

The present application claims priority under 35 U.S.C. § 119(a) to Korean patent application number 10-2022-0033632 filed on Mar. 17, 2022, in the Korean Intellectual Property Office, the entire disclosure of which is incorporated by reference herein.

### BACKGROUND

### 1. Technical Field

The present disclosure generally relates to a memory device and a manufacturing method of the memory device, and more particularly, to a three-dimensional memory device and a manufacturing method of the three-dimensional memory device.

### 2. Related Art

A memory device may be generally classified as a volatile memory device, from which stored data is lost when a supply of power is interrupted, or a nonvolatile memory device, in which stored data is retained even when the supply of power is interrupted.

A nonvolatile memory device may include NAND flash memory, NOR flash memory, resistive random access memory (ReRAM), phase-change random access memory (PRAM), magnetoresistive random access memory (MRAM), ferroelectric random access memory (FRAM), spin transfer torque random access memory (STT-RAM), or the like.

Nonvolatile memory devices should have excellent data retention characteristics. However, in memory devices having three-dimensional structures devised to improve a degree of integration, charge trap layers in which data is stored are connected to each other between different memory cells, and hence, data retention characteristics may be diminished.

### SUMMARY

Some embodiments are directed toward a memory device, and a manufacturing method of the memory device, having improved data retention characteristics.

In accordance with an embodiment of the present disclosure, a memory device includes: isolation layers and gate structures that are alternately stacked on a lower structure and a tunnel isolation layer penetrating the isolation layers and the gate structures. The memory device also includes a channel layer formed along an inner wall of the tunnel isolation layer; and a core plug formed along an inner wall of the channel layer. Each of the gate structures includes: a floating gate surrounding an outer wall of the tunnel isolation layer; a first dielectric layer surrounding an outer wall of the floating gate; a second dielectric layer surrounding an outer wall of the first dielectric layer; a third dielectric layer surrounding an outer wall of the second dielectric layer; and a gate line formed between the isolation layers, the gate line filling a region surrounded at least in part by the third dielectric layer.

In accordance with teachings of the present disclosure, a method of manufacturing a memory device includes: alternately stacking isolation layers and sacrificial layers on a lower structure; forming a vertical hole penetrating the isolation layers and the sacrificial layers; forming first recesses by removing portions of the sacrificial layers exposed by the vertical hole; forming a first dielectric layer along a respective inner wall of the sacrificial layers exposed through the first recesses; forming a floating gate inside a respective first recess in which the first dielectric layer is formed; forming a cell plug inside the vertical hole; forming second recesses by removing portions of the sacrificial layers to expose outer walls of the first dielectric layers; forming a second dielectric layer on a respective outer wall of the first dielectric layer; forming a third dielectric layer in a respective second recess along a respective outer wall of the second dielectric layers and along respective surfaces of the isolation layers; and forming a gate line inside a respective second recess in which the third dielectric layer is formed.

### BRIEF DESCRIPTION OF THE DRAWINGS

Various embodiments are described more fully hereinafter with reference to the accompanying drawings; however, these embodiments may be embodied in different forms and should not be construed as being limited to forms set forth herein. Rather, these embodiments are provided so that this disclosure will be enabling to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout the detailed description.

FIG. 1 is a diagram illustrating an example memory device in accordance with an embodiment of the present disclosure.

FIG. 2 is a diagram illustrating an example arrangement structure of a memory cell array and a peripheral circuit.

FIG. 3 is a diagram illustrating an example structure of the memory cell array.

FIG. 4 is a circuit diagram illustrating an example structure of a memory block.

FIG. 5 is a sectional view illustrating an example structure of a memory device in accordance with an embodiment of the present disclosure.

FIGS. 6A and 6B are plan views illustrating an example structure of the memory device in accordance with an embodiment of the present disclosure.

FIG. 7 is a diagram illustrating an example energy band of an example memory cell.

FIGS. 8A to 8I are views illustrating an example manufacturing method of a memory device in accordance with an embodiment of the present disclosure.

FIG. 9 is a view illustrating an example structure of a memory device in accordance with another embodiment of the present disclosure.

FIG. 10 is a diagram illustrating an example Solid State Drive (SSD) system to which the memory device of the present disclosure is applied.

FIG. 11 is a diagram illustrating an example memory card system to which the memory device of the present disclosure is applied.

### DETAILED DESCRIPTION

Specific structural or functional descriptions disclosed herein are merely illustrative for the purpose of describing embodiments according to the concept of the present disclosure. Embodiments according to the concept of the present disclosure can be implemented in various forms and should not be construed as being limited to the embodiments set forth herein.

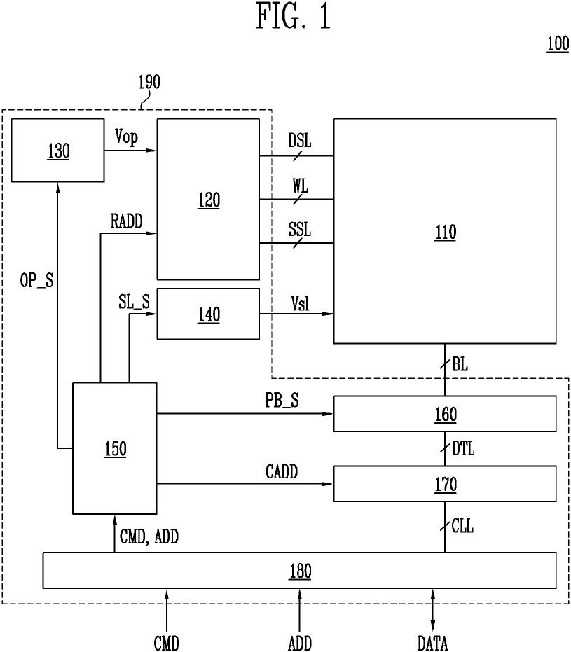

FIG. 1 is a diagram illustrating an example memory device 100 in accordance with an embodiment of the present disclosure.

Referring to FIG. 1, the memory device 100 may include a peripheral circuit 190 and a memory cell array 110.

The peripheral circuit 190 may be configured to perform a program operation and a verify operation, which are used to store data; to perform a read operation, for outputting data stored in the memory cell array; or to perform an erase operation, for erasing data stored in the memory cell array 110. The peripheral circuit 190 may include a voltage generating circuit 130, a row decoder 120, a source line driver 140, a control circuit 150, a page buffer 160, a column decoder 170, and an input-output circuit 180.

The memory cell array 110 may include a plurality of memory cells in which data is stored. In an embodiment, the memory cell array 110 may include a three-dimensional memory cell array. The plurality of memory cells may store single-bit data or multi-bit data of two or more bits according to a program manner. The plurality of memory cells may constitute a plurality of strings. Memory cells included in each of the strings may be electrically connected to each other through a channel. Channels included in the strings may be connected to the page buffer 160 through bit lines BL.

The voltage generating circuit 130 may generate various operating voltages Vop used for a program operation, a read operation, or an erase operation in response to an operation signal OP_S. For example, the voltage generating circuit 130 may selectively generate and output the operating voltages Vop including a program voltage, a verify voltage, a pass voltage, a read voltage, an erase voltage, and the like.

The row decoder 120 may be connected to the memory cell array 110 through a plurality of drain select lines DSL, a plurality of word lines WL, and a plurality of source select lines SSL. The row decoder 120 may transfer the operating voltages Vop to the plurality of drain select lines DSL, the plurality of word lines WL, and the plurality of source select lines SSL in response to a row address RADD.

The source line driver 140 may transmit a source voltage Vsl to the memory cell array 110 in response to a source line control signal SL_S. For example, the source voltage Vsl may be transferred to a source line connected to the memory cell array 110.

The control circuit 150 may output the operation signal OP_S, the row address RADD, the source line control signal SL_S, a page buffer control signal PB_S, and a column address CADD, in response to a command CMD and an address ADD.

The page buffer 160 may be connected to the memory cell array 110 through the bit lines BL. The page buffer 160 may temporarily store data DATA received through the plurality of bit lines BL in response to the page buffer control signal PB_S. The page buffer 160 may sense a voltage or current of the plurality of bit lines BL in a read operation.

The column decoder 170 may transmit data DATA input from the input-output circuit 180 to the page buffer 160 or transmit data DATA stored in the page buffer 160 to the input-output circuit 180, in response to the column address CADD. The column decoder 170 may exchange data DATA with the input-output circuit 180 through column lines CLL, and exchange data DATA with the page buffer 160 through data lines DTL.

The input-output circuit 180 may transfer, to the control circuit 150, a command CMD and an address ADD, which are transferred from an external device (e.g., a controller) connected to the memory device 100, and output data received from the column decoder 170 to the external device.

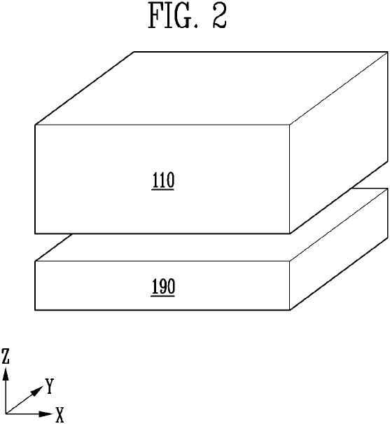

FIG. 2 is a diagram illustrating an example arrangement structure of the memory cell array 110 and the peripheral circuit 190.

Referring to FIG. 2, in a memory device having a three-dimensional structure, the memory cell array 110 may be stacked above the peripheral circuit 190. For example, when a substrate defines an X-Y plane, the peripheral circuit 190 may be stacked in a Z direction above the substrate, and the memory cell array 110 may be stacked above the peripheral circuit 190.

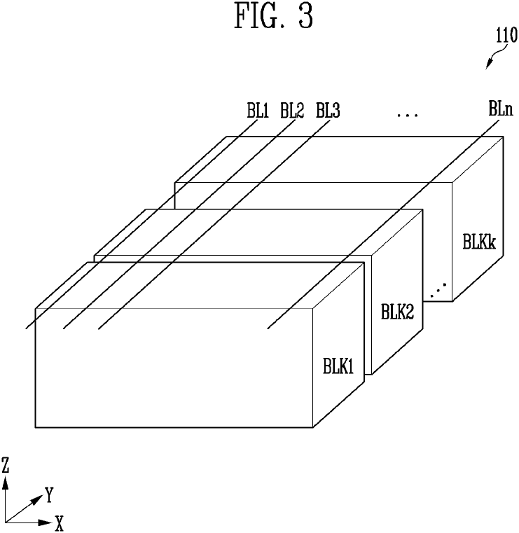

FIG. 3 is a diagram illustrating an example structure of the memory cell array.

Referring to FIG. 3, the memory cell array 110 may include first to kth memory blocks BLK1 to BLKk (k is a positive integer). The first to kth memory blocks BLK1 to BLKk may be arranged to be spaced apart from each other along a Y direction, and be commonly connected to first to nth bit lines BL1 to BLn. For example, the first to nth bit lines BL1 to BLn may extend along the Y-direction, and be disposed to be spaced apart from each other along an X direction. The first to kth memory blocks BLK1 to BLKk may include a plurality of cell plugs (not shown) extending in the Z direction. The cell plugs may include a plurality of memory cells capable of storing data. A structure of a memory block including a plurality of cell plugs will be described in detail as follows.

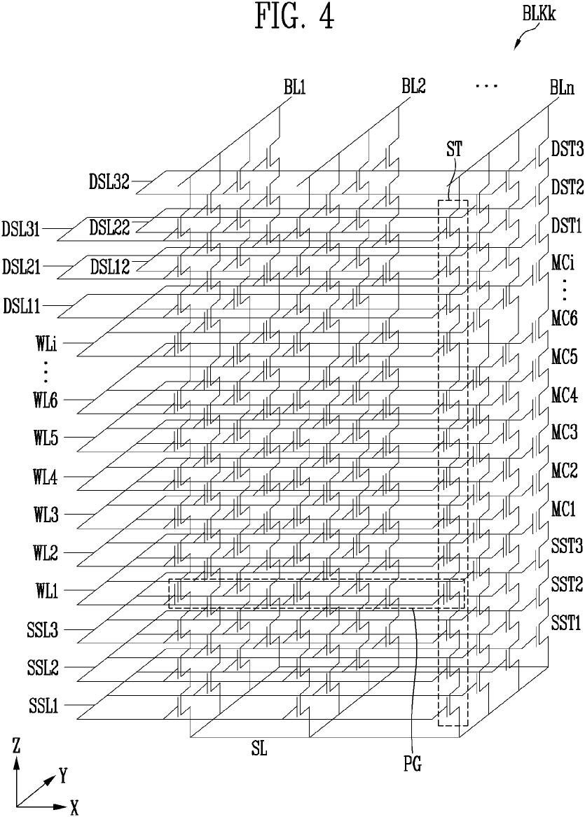

FIG. 4 is a circuit diagram illustrating an example structure of a memory block.

Referring to FIG. 4, the first to kth memory blocks (BLK1 to BLKk, which are shown in FIG. 2) are configured identically to one another, and therefore, the kth memory block BLKk among the first to kth memory blocks BLK1 to BLKk is illustrated as an example.

The kth memory block BLKk may include strings ST connected between the first to nth bit lines BL1 to BLn and a source line SL. Because the first to nth bit lines BL1 to BLn extend along a second direction (Y direction) and are arranged to be spaced apart from each other along a first direction (X direction), the strings ST may also be arranged to be spaced apart from each other along the first and second directions (X and Y directions). For example, the strings ST may be connected between the first bit line BL1 and the source line SL, and the strings ST may be arranged between the second bit line BL2 and the source line SL. In this manner, the strings ST may be arranged between the nth bit line BLn and the source line SL. The strings ST may extend along a third direction (Z direction).

Any one string ST among the strings ST connected to the nth bit line BLn will be described as an example. The string ST may include first to third source select transistors SST1 to SST3, first to ith memory cells MC1 to MCi, and first to third drain select transistors DST1 to DST3. The kth memory block BLKk shown in FIG. 4 is a drawing for describing the structure of a memory block, and therefore, the numbers of source select transistors, memory cells, and drain select transistors, which are included in the strings ST, may be changed according to a memory device.

Gates of first to third source select transistors SST1 to SST3 included in different strings may be connected to first to third source select lines SSL1 to SSL3; gates of first to ith memory cells MC1 to MCi, which are included in different strings, may be connected to first to ith word lines WL1 to WLi; and gates of first to third drain select transistors DST1 to DST3, which are included in different strings, may be connected to eleventh, twelfth, twenty-first, twenty-second, thirty-first, and thirty-second drain select lines DSL11, DSL12, DSL21, DSL22, DSL31, and DSL32. It should be noted that ordinal numbers may be used herein for clarity in referring to an item in a figure, and need not necessarily indicate a number of items. For example, “thirty-second drain select line DSL32” does not necessarily indicate that there are thirty-two separate drain select lines.

In an embodiment, the first source select line SSL1 and the first source transistors SST1 may be formed on a first layer. The second source select line SSL2 and the second source transistors SST2 may be formed on a second layer. The third source select line SSL3 and the third source transistors SST3 may be formed on a third layer. That is, the first layer, the second layer, and the third layer may be different layers that are each at a different distance from the substrate. The first source select transistors SST1 may be commonly connected to the first source select line SSL1. The second source select transistors SST2 may be commonly connected to the second source select line SSL2. The third source select transistors SST3 may be commonly connected to the third source select line SSL3.

In the manner described above, ith memory cells MCi formed in the same layer may be commonly connected to the ith word line WLi, and the first to ith word lines WL1 to WLi may be respectively formed in different layers. A group of memory cells included in different strings ST and connected to the same word line may be referred to as a page PG.

The first to third drain select transistors DST1 to DST3 included in the different strings ST may be respectively connected to drain select lines isolated from each other. Specifically, each of first to third drain select transistors DST1 to DST3 arranged along the first direction (X direction) may be connected to the same drain select line, and the first to third drain select transistors DST1 to DST3 arranged along the second direction (Y direction) may be respectively connected to the drain select lines isolated from each other. For example, some of the first drain select transistors DST may be connected to the eleventh drain select line DSL11, and the other of the first drain select transistors DST may be connected to the twelfth drain select line DSL12. The twelfth drain select line DSL12 is a line isolated from the eleventh drain select line DSL11. Therefore, a voltage applied to the eleventh drain select line DSL11 may be different from a voltage applied to the twelfth drain select line DSL12. In this manner, some of the second drain select transistors DST2 may be connected to the twenty-first drain select transistor DSL21, and the other of the second drain select transistors DST2 may be connected to the twenty-second drain select line DSL22. Some of the third drain select transistors DST3 may be connected to a thirty-first drain select line DSL31, and the other of the third drain select transistors DST3 may be connected to the thirty-second drain select line DSL 32.

FIG. 5 is a sectional view illustrating an example structure of a memory device in accordance with an embodiment of the present disclosure.

Referring to FIG. 5, a memory block included in the memory device 100 may include isolation layers IS and gate structures GSR, which are alternately stacked, and a cell plug CPL vertically penetrating the isolation layers IS and the gate stack structures GSR. The isolation layers IS may be formed of isolation material such as, for example, dielectric materials. Various examples of dielectric materials are provided in the following paragraphs. For example, the isolation layer IS may be formed of, for example, an oxide such as a silicon oxide.

The gate structures GSR may include floating gates FG, first to third dielectric layers 1DE to 3DE, and gate lines GL. The floating gate FG may be used as a layer for storing electrons e as negative charges. The floating gate FG may be formed, for example, in a tubular shape surrounding the cell plug CPL. A “tubular shape” may also be referred to as being “cylindrical” or a “cylindrical shape” as the word “cylinder” can refer to a shape that has a solid body or a hollow body. Additionally, a tubular shaped body may be referred to as a “cylinder,” a “hollow cylinder,” or a body having a “tubular shape” A tubular shaped body may be said to have an “inner wall” (or “inner sidewall”) and an “outer wall” (or and “outer sidewall”), where generally the inner wall is closer to a center of the tubular shaped body and the outer wall is farther away from the center of the tubular shaped body.

The floating gate FG may be formed of a material having a high work function to store electrons e and to maintain the stored electrons. For example, the floating gate FG may be formed of titanium nitride (TiN), tantalum nitride (TaN), etc. Accordingly, the floating gate FG may be formed of various materials capable of storing electrons e. The first dielectric layer 1DE may be formed to surround the floating gate FG. The first dielectric layer 1DE may be formed of a material that has the lowest permittivity among the first to third dielectric layers 1DE to 3DE and has the highest band gap energy among the first to third dielectric layers 1DE to 3DE. For example, the first dielectric layer 1DE may be formed of silicon oxide (SiₓO_{y}). The second dielectric layer 2DE may be formed to surround the first dielectric layer 1DE. The second dielectric layer 2DE may be formed of a material that has the highest permittivity among the first to third dielectric layers 1DE to 3DE and has the lowest band gap energy among the first to third dielectric layers 1DE to 3DE. For example, the second dielectric layer 2DE may be formed of at least one material selected from silicon nitride (SiₓN_{y}), hafnium oxide (HfₓO_{y}), zirconium oxide (ZrₓO_{y}), zirconium silicate (ZrₓSiO_{y}), hafnium silicate (HfₓSiO_{y}), etc. The third dielectric layer 3DE may be formed to surround the second dielectric layer 2DE and the gate line GL. The third dielectric layer 3DE may be formed of a material having a permittivity higher than the permittivity of the first dielectric layer 1DE. For example, the third dielectric layer 3DE may be formed of aluminum oxide (AlₓO_{y}).

In chemical formulae of the materials constituting the first to third dielectric layers 1DE to 3DE, x and y may be real numbers. Also, x and y in different chemical formulae may be different real numbers. For example, in an embodiment, the first dielectric layer 1DE may be formed of SiO₂, the second dielectric layer 2DE may be formed of at least one material selected from Si₃N₄, HfO, ZrO₂, ZrSiO₄, and HfSiO₄, and the third dielectric layer 3DE may be formed of Al₂O₃. In addition, the first to third dielectric layers 1DE to 3DE may be formed of various other materials, including combination of materials.

The gate lines GL are layers used as select lines or word lines, and may be surrounded at least in part by the third dielectric layer 3DE. For example, FIG. 5 shows an embodiment where each gate line GL is surrounded on 3 sides by the third dielectric layer 3DE. The gate lines GL may be formed as a conductive layer or a semiconductor layer to transfer operating voltages. For example, the gate lines GL may be formed of a conductive material such as tungsten (W), molybdenum (Mo), cobalt (Co), nickel (Ni), etc., or a semiconductor material such as silicon (Si), poly-silicon (Poly-Si), etc. Accordingly, the gate lines GL may be formed of various metal materials or various semiconductor materials.

The cell plug CPL may include a core plug CP, a channel layer CH, and a tunnel isolation layer Tox, which vertically penetrate the isolation layers IS and the floating gates FG. The core plug CP may be formed as an isolation layer having, for example, a cylindrical shape. For example, the core plug CP may be formed as an oxide layer or a silicon oxide layer. The channel layer CH may be formed to surround a side surface of the core plug CP, and be formed of poly-silicon. The tunnel isolation layer Tox may be formed to surround a side surface of the channel layer CH, and be formed of the same material as the first dielectric layer 1DE. For example, the tunnel isolation layer Tox may be formed of silicon oxide (SiₓO_{y}). The floating gate FG may be formed in a tubular shape surrounding the tunnel isolation layer Tox.

In this embodiment, the floating gates FG spaced apart from each other along a vertical direction (Z direction) are formed instead of charge trap layers extending along the vertical direction, so that a phenomenon, illustrated at 51, can be suppressed. The suppressed phenomenon is one in which electrons e stored in a floating gate FG of a selected memory cell are diffused or moved upwardly or downwardly. The isolation layers IS are formed between the floating gates FG included in the gate structures GSR of different layers, so that emission of electrons e stored in the floating gate FG can be suppressed. Thus, in the memory device in accordance with this embodiment, a retention characteristic may be improved.

A planar structure in which the gate structures GSR are formed and a planar structure in which the isolation layers IS are formed will be described as follows with reference to a section taken along a direction AA-AA′ and a section taken along a direction BB-BB′.

FIGS. 6A and 6B are plan views illustrating an example structure of the memory device in accordance with an embodiment of the present disclosure.

FIG. 6A is a plan view taken along the direction AA-AA′ shown in FIG. 5, and FIG. 6B is a plan view taken along the direction BB-BB′ shown in FIG. 5.

Referring to FIGS. 6A and 5, on a plane (AA-AA′) in which the gate structure GSR is formed, the core plug CP may be formed, for example, in a cylindrical shape at the center of the cell plug CPL. The channel layer CH may be formed to surround the side surface of the core plug CP, and the tunnel isolation layer Tox may be formed to surround the side surface of the channel layer CH. The floating gate FG in which data is stored may be formed to surround a side surface of the tunnel isolation layer Tox, and the first to third dielectric layers 1DE to 3DE may be formed to sequentially surround a side surface of the floating gate FG. For example, the first dielectric layer 1DE may be formed to surround the side surface of the floating gate FG, the second dielectric layer 2DE may be formed to surround a side surface of the first dielectric layer 1DE, and the third dielectric layer 3DE may be formed to surround a side surface of the second dielectric layer 2DE. The gate line GL may be formed to surround a side surface of the third dielectric layer 3DE.

Referring to FIGS. 6B and 5, on a plane (BB-BB′) in which the isolation layer IS is formed, the core plug CP may be formed in a cylindrical shape at the center of the cell plug CPL. The channel layer CH may be formed to surround the side surface of the core plug CP, and the tunnel isolation layer Tox may be formed to surround the side surface of the channel layer CH. The isolation layer IS may be formed to surround the side surface of the tunnel isolation layer Tox. The floating gate FG in which data is stored is not formed in a layer in which the gate structure GSR is not formed.

FIG. 7 is a diagram illustrating an example energy band of an example memory cell. Energy bands of material layers formed in a partial region 52 shown in FIG. 5.

Referring to FIG. 7, in order to prevent electrons stored in the floating gates FG from being released to the outside, the tunnel isolation layer Tox and the first dielectric layer 1DE, which have a high energy band gap, may be disposed at both ends of the floating gate FG.

When assuming that the Fermi level of the floating gate FG is a first level E1, a conduction band CB of the tunnel isolation layer Tox and the first dielectric layer 1DE may have a second level E2 higher than the first level E1, and a valence band VB of the tunnel isolation layer Tox and the first dielectric layer 1DE may have a third level E3 lower than the first level E1. For example, the tunnel isolation layer Tox and the first dielectric layer 1DE may be formed of a material having a first energy band gap 1BG that is highest among the material layers included in the gate structure GSR. Therefore, the electrons stored in the floating gate FG are not released to the outside by the tunnel isolation layer Tox and the first dielectric layer 1DE until a voltage having a level higher than the second level E2 is applied. That is, a back tunneling phenomenon can be suppressed due to the first dielectric layer 1DE.

The second dielectric layer 2DE may be formed of a material having a second energy band gap 2BG lower than the first energy band gap 1BG of the first dielectric layer 1DE so as to increase a coupling ratio of the second dielectric layer 2DE with the gate line GL. The third dielectric layer 3DE may be formed of a material having a third energy band gap 3BG higher than the second energy band gap of the second dielectric layer 2DE so as to prevent the electrons stored in the floating gate FG from being released toward the gate line GL. For example, the third energy band gap 3BG may be higher than the second energy band gap 2BG and be lower than the first energy band gap 1BG.

Also, the third dielectric layer 3DE may be formed of a material having a permittivity higher than a permittivity of the first dielectric layer 1DE so as to transfer the voltage applied to the gate line GL to the second dielectric layer DE. For example, the first dielectric layer 1DE may be formed of a material having a first permittivity (1ε) that is lowest, and the third dielectric layer 3DE may be formed of a material having a second permittivity (2ε) higher than the first permittivity (1ε).

That is, the third dielectric layer 3DE may be formed of a material that has a permittivity higher than the permittivity of the first dielectric layer 1DE and has an energy band gap higher than the energy band gap of the second dielectric layer 2DE.

The tunnel isolation layer Tox may be formed of a material having the first energy band gap 1BG so the electrons stored in the floating gate FG are not released to the channel layer CH until a voltage having a level higher than the second level E2 is applied.

A manufacturing method of the above-described memory device is described in detail as follows.

FIGS. 8A to 8I are views illustrating an example manufacturing method of the memory device in accordance with an embodiment of the present disclosure.

Referring to FIG. 8A, isolation layers IS and sacrificial layer SC may be alternately stacked on a lower structure LS. The lower structure LS may be a substrate, peripheral circuits, or a source line. The isolation layers IS may be formed, for example, as an oxide layer or a silicon oxide layer, and the sacrificial layers SC may be formed, for example, of a material that has a high permittivity and has a low energy band gap. For example, the sacrificial layers SC may be formed of a material selected from silicon nitride (SiₓN_{y}), hafnium oxide (HfₓO_{y}), zirconium oxide (ZrₓO_{y}), zirconium silicate (ZrₓSiO_{y}), hafnium silicate (HfₓSiO_{y}), etc.

Referring to FIG. 8B, a first etching process for forming a vertical hole VH penetrating the isolation layers IS and the sacrificial layers SC in a vertical direction Z may be performed, and a second etching process for forming first recesses 1RC by removing portions of the sacrificial layers SC exposed through the vertical hole VH may be performed. The first etching process may be performed as, for example, a dry etching process, and be performed as, for example, an anisotropic etching process such that the vertical hole VH is formed at a position at which a cell plug is to be formed in the vertical (Z) direction.

The second etching process may be performed as, for example, an isotropic etching process to remove portions of the sacrificial layers SC among the isolation layers IS and the sacrificial layers SC, which are exposed through a side surface of the vertical hole VH. For example, the second etching process may be performed by using an etching gas having an etch selectivity of the sacrificial layers SC, which is higher than an etch selectivity of the isolation layer IS. The second etching process may be performed such that the first recesses 1RC are formed according to thicknesses with which the first dielectric layer (1DE shown in FIG. 5) and the floating gate (FG shown in FIG. 5). For example, the second etching process may be performed such that a depth DEP of the first recesses 1RC is equal to a sum of thicknesses of the first dielectric layer (1DE shown in FIG. 5) and the floating gate (FG shown in FIG. 5). The depth DEP of the first recesses 1RC may be in the X direction.

Referring to FIG. 8C, a first dielectric layer 1DE may be formed along side surfaces of the sacrificial layers SC exposed in the first recesses 1RC. The first dielectric layer 1DE may be formed, for example, by performing a radical oxidation process to be selectively formed on the sacrificial layers SC among the isolation layers IS and the sacrificial layers SC, which are exposed through the first recesses 1RC. For example, the first dielectric layer 1DE may be formed of SiO₂.

Referring to FIG. 8D, a material layer for a floating gate FG may be formed inside the first recesses 1RC between the isolation layers IS. The material layer for the floating gate FG is a layer for storing electrons, and may be formed of a material having a high work function. For example, the floating gate FG may be formed of titanium nitride (TiN), tantalum nitride (TaN), etc., and may be formed through, for example, an atomic layer deposition (ALD) process. When the material layer for the floating gate FG is formed to be sufficiently filled inside the first recesses 1RC, the material layer for the floating gate FG may even be formed, for example, on side surfaces of the isolation layers IS exposed through an inner wall of the vertical hole VH.

Referring to FIG. 8E, a third etching process may be performed such that the material layer for the floating gate FG, which is formed in the first recesses 1RC, remain and the material layer for the floating gate FG, which is formed along the inner wall of the vertical hole VH, is removed. The material layer for the floating gate FG may become floating gates FG spaced apart from each other in different layers through the third etching process.

Referring to FIG. 8F, a cell plug CPL may be formed inside the vertical hole VH. For example, a tunnel isolation layer Tox, a channel layer CH, and a core plug CP may be sequentially formed along the inner wall of the vertical hole VH, thereby forming the cell plug CPL. The tunnel isolation layer Tox may be formed of, for example, the same material as the first dielectric layer 1DE, and may be formed, for example, in a tubular shape. For example, the tunnel isolation layer Tox may be formed of silicon oxide SiO₂ having a tubular shape. The channel layer CH may be formed, for example, in the tubular shape along an inner wall of the tunnel isolation layer Tox. For example, the channel layer CH may be formed of poly-silicon. The core plug CP may be formed in the hollow portion of the channel layer CH and may be formed along an inner wall of the channel layer CH. For example, the core plug CP may be formed as an oxide layer or a silicon oxide layer. Although not shown in the drawing, in an embodiment, a conductive layer vertically penetrating the core plug CP may be further formed in a central region of the core plug CP.

Referring to FIG. 8G, a fourth etching process for removing portions of the sacrificial layers SC formed between the isolation layers IS may be performed. Second recesses 2RC are formed by removing portions of the sacrificial layers SC through the fourth etching process, and the fourth etching process may be performed such that portions of the sacrificial layers SC formed on the side surface of the first dielectric layer 1DE remain. For example, the fourth etching process may be performed as a wet etching process using an etchant having an etch selectivity of the sacrificial layers SC, which is higher than an etch selectivity of the isolation layers IS, or be performed as an isotropic dry etching process using a gas having an etch selectivity of the sacrificial layers SC, which is higher than an etch selectivity of the isolation layers IS.

All the sacrificial layers SC in the second recesses 2RC may be removed due to the fourth etching process. Therefore, after the fourth etching process is performed, a selective deposition process for selectively forming a second dielectric layer 2DE on the side surface of the first dielectric layer 1DE may be performed. In an embodiment, the selective deposition process may be performed as a thermal atomic layer deposition process of, for example, 650° C. or higher.

Referring to FIG. 8H, a third dielectric layer 3DE may be formed along inner surfaces of the second recesses 2RC. The isolation layers IS and the second dielectric layer 2DE are exposed through the inside of the second recesses 2RC, and therefore, the third dielectric layer 3DE may be formed along surfaces of the isolation layers IS and the second dielectric layer 2DE, which are exposed through the second recesses 2RC. The third dielectric layer 3DE may be formed of a material having a permittivity higher than the permittivity of the first dielectric layer 1DE. For example, the third dielectric layer 3DE may be formed of aluminum oxide (Al₂O₃). The third dielectric layer 3DE may be formed by performing a deposition process using thermal atomic layer deposition of, for example, 650° C. or higher.

Referring to FIG. 8I, gate lines GL may be formed in the second recesses 2RC in which the third dielectric layer 3DE is formed. The gate lines GL may be used as select lines or word lines. Therefore, each of the gate lines GL may be formed as a conductive layer or a semiconductor layer to transfer operating voltages. For example, the gate lines GL may be formed of a conductive material such as tungsten (W), tungsten nitride (WN), titanium nitride (TiN), molybdenum (Mo), cobalt (Co), nickel (Ni), etc, or a semiconductor material such as silicon (Si), poly-silicon (Poly-Si), etc. Accordingly, the gate lines GL may be formed of various metal materials or various semiconductor materials.

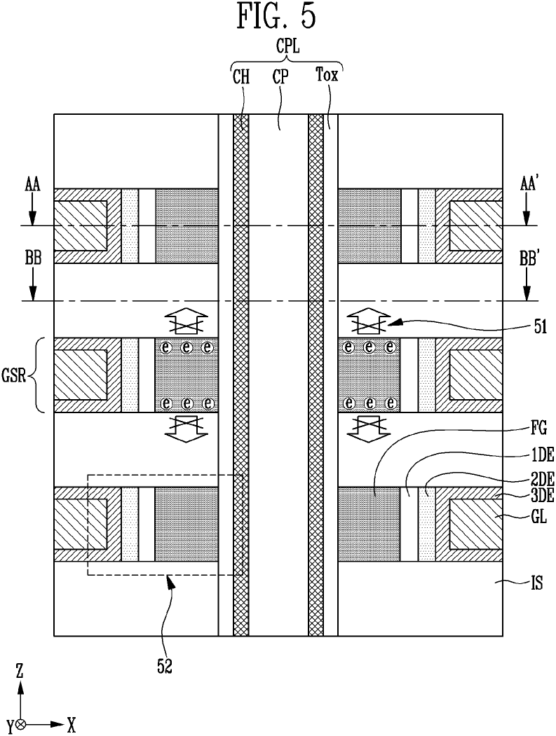

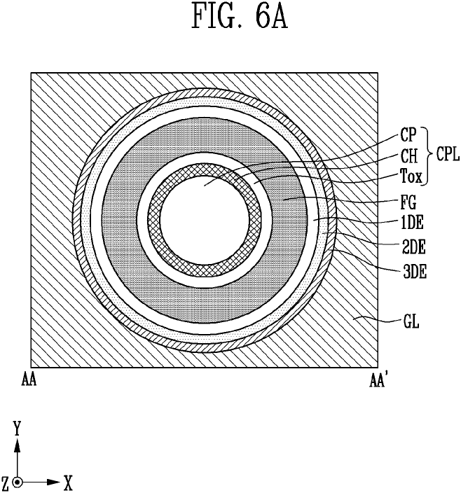

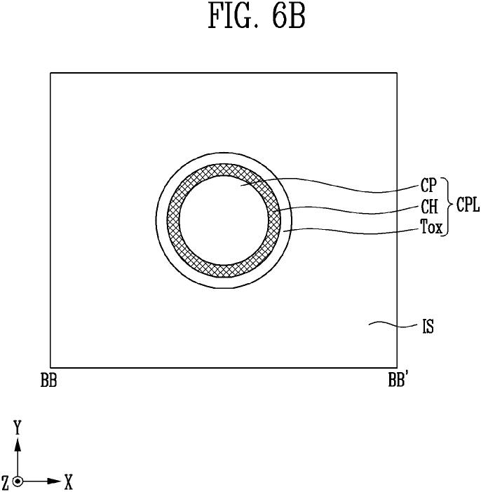

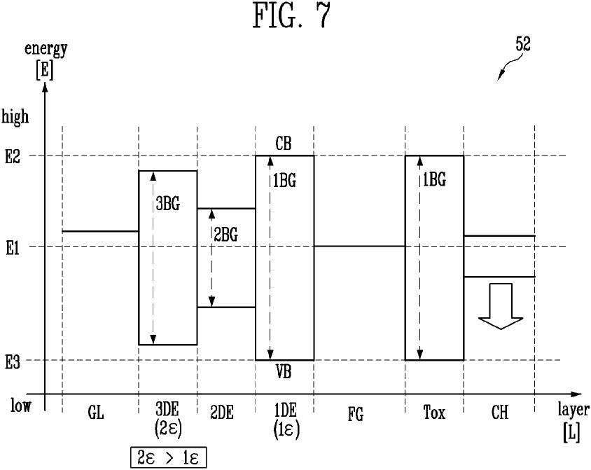

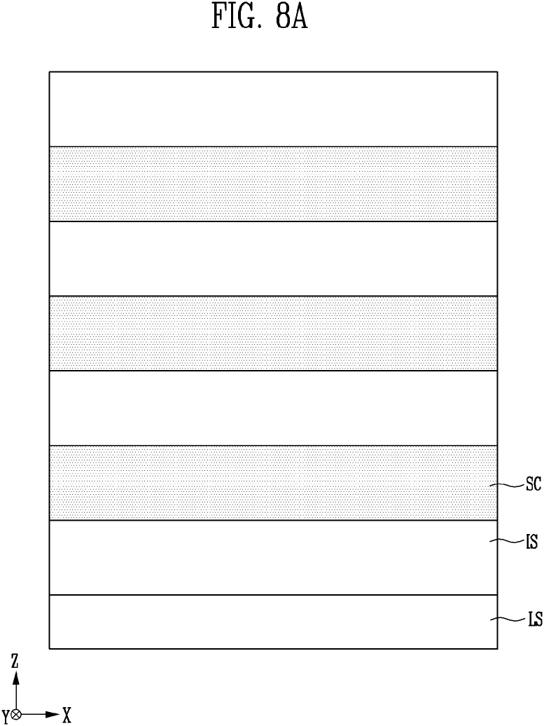

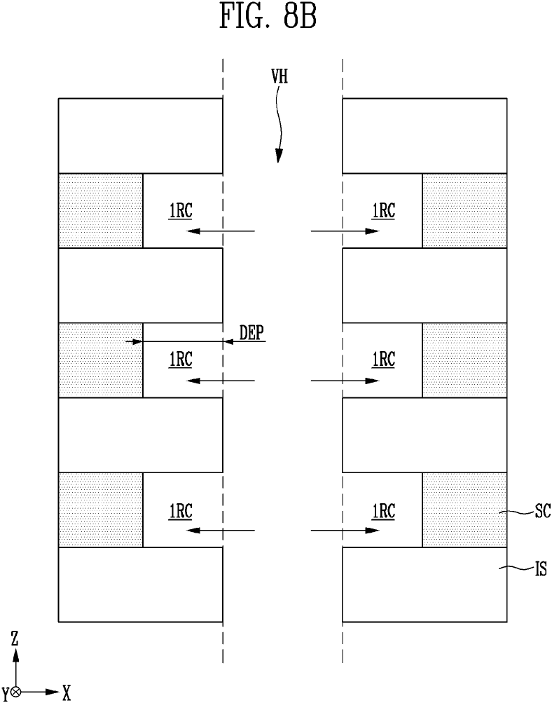

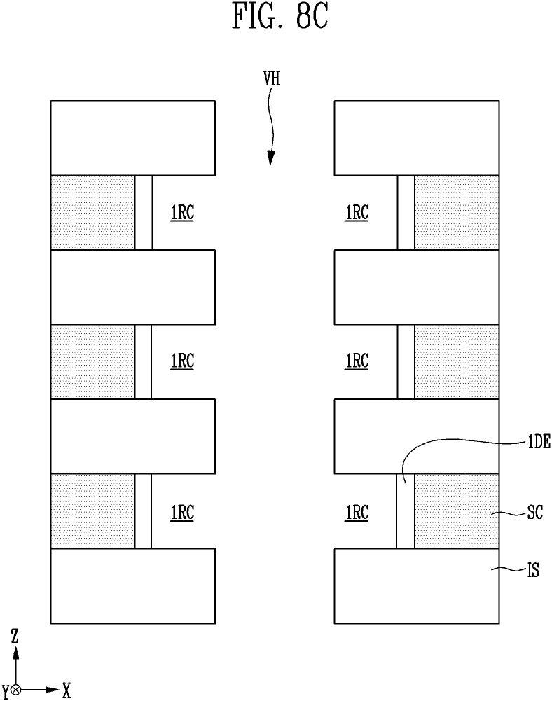

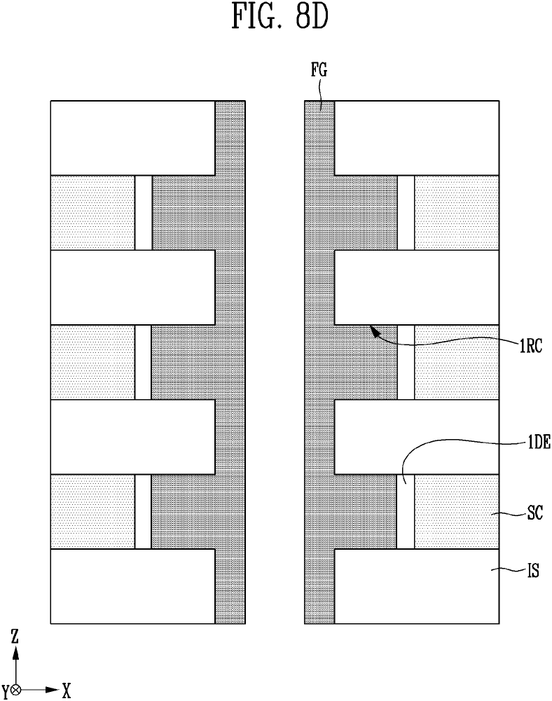

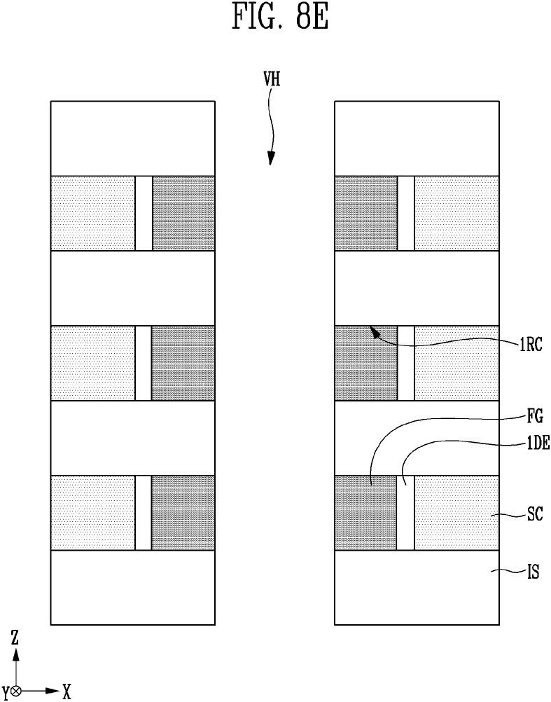

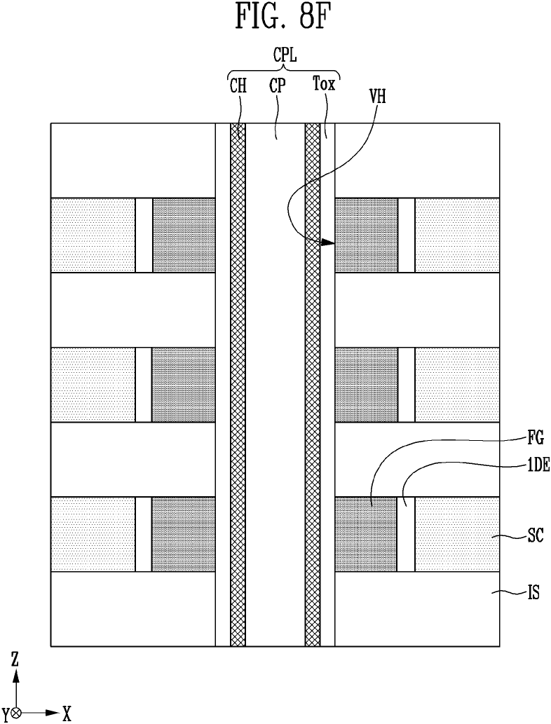

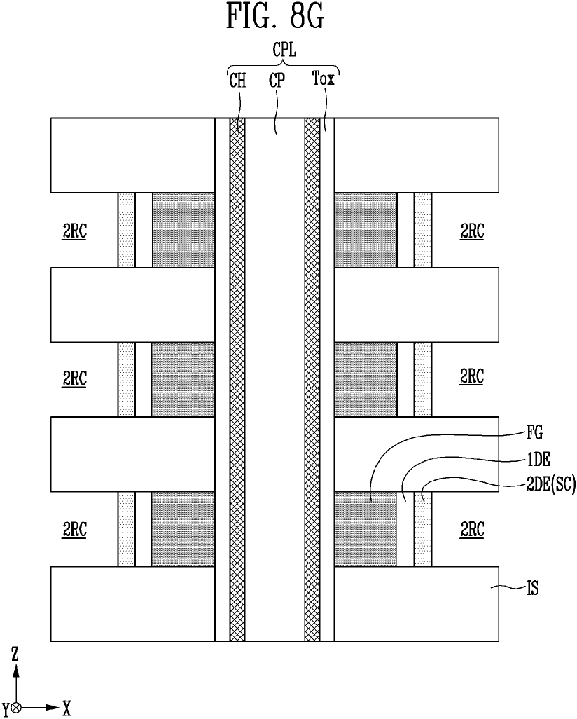

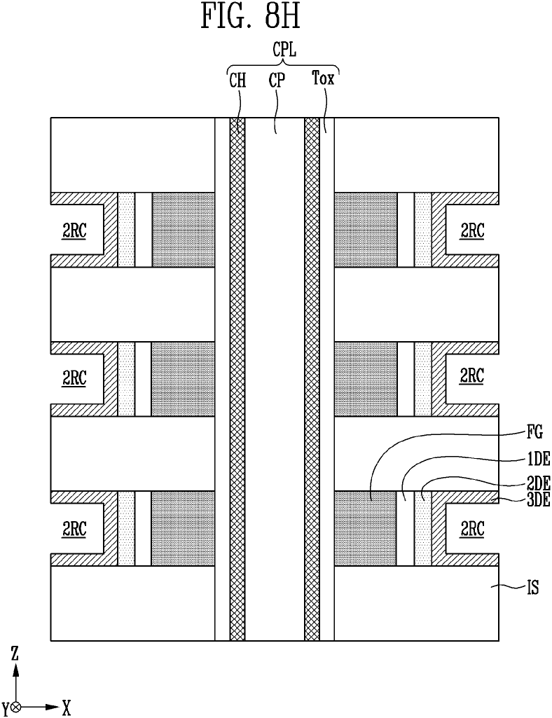

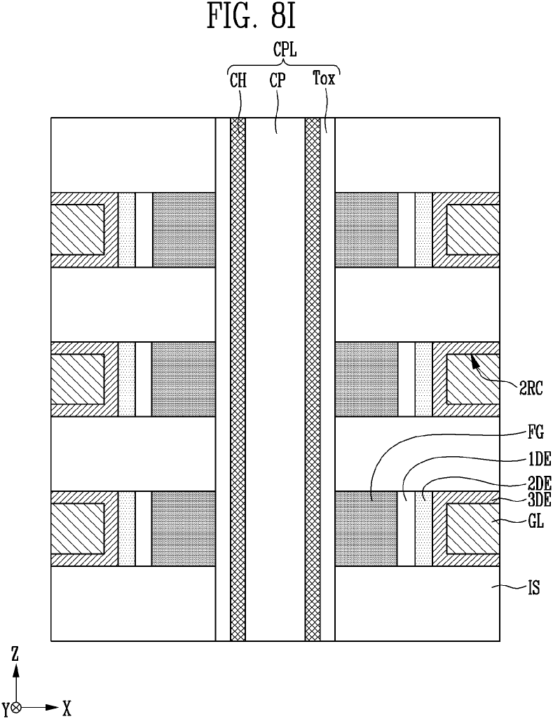

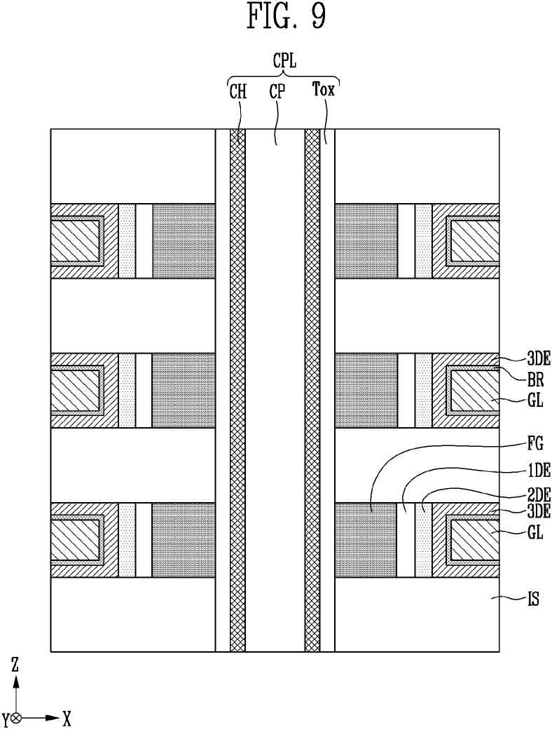

FIG. 9 is a view illustrating an example structure of a memory device in accordance with another embodiment of the present disclosure.

Referring to FIG. 9, in some embodiments, barrier layers BR may be further formed between the gate lines GL and the third dielectric layer 3DE. The barrier layers BR may prevent diffusion of impurities between the gate lines GL and the third dielectric layer 3DE. The barrier layer BR may be formed of, for example, tungsten nitride (WN), titanium nitride (TiN), etc. The other components except the barrier layer BR are identical to those shown in FIG. 5, and therefore, repeated descriptions of components already described in conjunction FIG. 5 will be omitted.

FIG. 10 is a diagram illustrating an example Solid State Drive (SSD) system 4000 to which the memory device of the present disclosure is applied.

Referring to FIG. 10, the SSD system 4000 includes a host 4100 and an SSD 4200. The SSD 4200 may exchange a signal with the host 4100 through a signal connector 4001, and be supplied with power through a power connector 4002. The SSD 4200 includes a controller 4210, a plurality of flash memories 4221 to 422n, an auxiliary power supply 4230, and a buffer memory 4240. While the plurality of flash memories is referred to with labels 4221 to 422n to simplify explanation, various embodiments of the disclosure need not be limited to ‘n’ representing a single digit.

In accordance with an embodiment of the present disclosure, each of the plurality of flash memories 4221 to 422n may be configured identically or substantially similarly to the memory device 100 described with reference to FIG. 1.

The controller 4210 may control the plurality of flash memories 4221 to 422n in response to a signal received from the host 4100. For example, the signal may be a signal based on an interface between the host 4100 and the SSD 4200. For example, the signal may be a signal defined by at least one of interfaces such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, an NVMe, etc.

The auxiliary power supply 4230 may be connected to the host 4100 through the power connector 4002. The auxiliary power supply 4230 may receive power PWR input from the host 4100 and charge the power PWR. When the supply of power from the host 4100 is not within, for example, design and/or implementation tolerances, the auxiliary power supply 4230 may provide power for the SSD 4200. The tolerances may specify, for example, voltage, current, amount of time for power out of tolerance, etc. For example, the auxiliary power supply 4230 may be located in the SSD 4200, or be located outside of the SSD 4200. For example, the auxiliary power supply 4230 may be located on a main board on which the SSD 4200 is located, and provide auxiliary power to the SSD 4200.

The buffer memory 4240 may be used as a buffer memory of the SSD 4200. For example, the buffer memory 4240 may temporarily store data received from the host 4100 or data received from the plurality of flash memories 4221 to 422n, or temporarily store metadata (e.g., a mapping table) of the plurality of flash memories 4221 to 422n. The buffer memory 4240 may include volatile memory such as DRAM, SDRAM, DDR SDRAM, LPDDR SDRAM, and/or GRAM or may include nonvolatile memory such as FRAM, ReRAM, STT-MRAM, and/or PRAM.

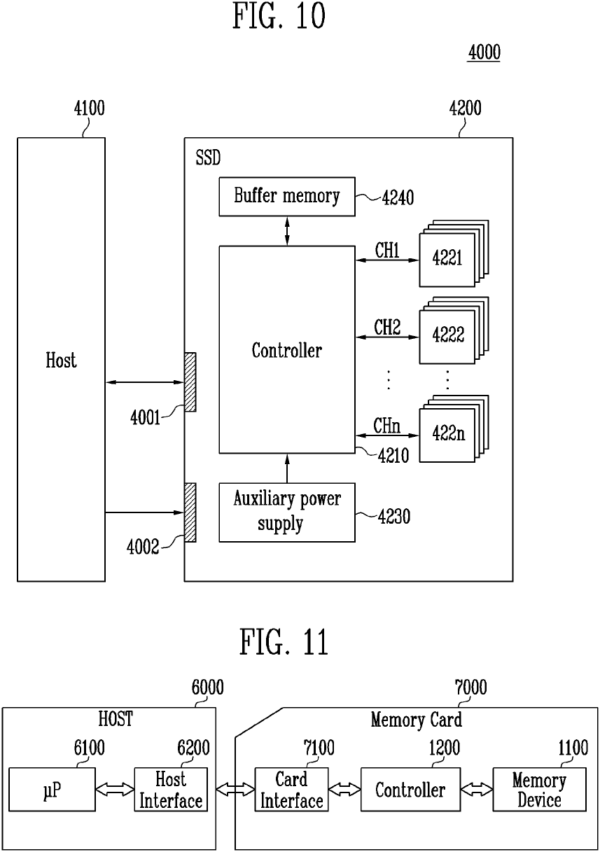

FIG. 11 is a diagram illustrating an example memory card system 7000 to which the memory device of the present disclosure is applied.

Referring to FIG. 11, the memory system 7000 may be implemented as a memory card or a smart card. The memory system 7000 may include a memory device 1100, a controller 1200, and a card interface 7100.

The memory device 1100 may be configured identically or substantially similarly to the memory device 100 shown in FIG. 1.

The controller 1200 may control data exchange between the memory device 1100 and the card interface 7100. In some embodiments, the card interface 7100 may be a secure digital (SD) card interface or a multi-media card (MMC) interface, but the present disclosure is not limited thereto.

The card interface 7100 may interface data exchange between a host 6000 and the controller 1200 according to a protocol of the host 6000. In some embodiments, the card interface 7100 may support a universal serial bus (USB) protocol and/or an inter-chip (IC)-USB protocol. The card interface 7100 may mean hardware capable of supporting a protocol used by the host 6000, software embedded in the hardware, or a signal transmission scheme.

When the memory system 7000 is connected to a host interface 6200 of the host 6000 such as, for example, a PC, a tablet PC, a digital camera, a digital audio player, a cellular phone, console video game hardware, a digital set-top box, etc., the host interface 6200 may perform data communication with the memory device 1100 through the card interface 7100 and the controller 1200 under the control of a microprocessor (µP) 6100.

While the present disclosure has been shown and described with reference to presented embodiments, it will be understood by those skilled in the art that various changes in form and detail may be made to the presented embodiments without departing from the spirit and scope of the present disclosure as defined by the appended claims and their equivalents. Therefore, the scope of the present disclosure should not be limited to the above-described presented embodiments but should be determined by not only the appended claims but also the equivalents thereof.

In the above-described embodiments, all steps may be selectively performed or some of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Some parts were described as being cylindrical or tubular in form. However, various embodiments need not be so limited as other geometrical shapes may be used. For example, rather than a cylinder, the shape may be a rectangular column, a triangular column, etc. Similarly, the tubular shape may be, for example, a hollow rectangular shape, etc.

Meanwhile, the presented embodiments of the present disclosure have been described in the drawings and specification. Although specific terminologies are used here, those are only to describe the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
isolation layers and gate structures, alternately stacked on a lower structure;
a tunnel isolation layer penetrating the isolation layers and the gate structures;
a channel layer formed along an inner wall of the tunnel isolation layer; and
a core plug formed along an inner wall of the channel layer,
wherein each of the gate structures includes:
a floating gate surrounding an outer wall of the tunnel isolation layer;
a first dielectric layer surrounding an outer wall of the floating gate;
a second dielectric layer surrounding an outer wall of the first dielectric layer;
a third dielectric layer surrounding an outer wall of the second dielectric layer; and
a gate line formed between the isolation layers, the gate line filling a region surrounded at least in part by the third dielectric layer.

2. The memory device of claim 1, wherein the core plug is formed in a cylindrical shape,
the channel layer is formed in a tubular shape surrounding a side surface of the core plug, and
the tunnel isolation layer is formed in a tubular shape surrounding a side surface of the channel layer.

3. The memory device of claim 1, wherein:
the core plug is formed of an isolation material,
the channel layer is formed of poly-silicon, and
the tunnel isolation layer is formed of silicon oxide.

4. The memory device of claim 1, wherein the floating gate is formed in a tubular shape surrounding the tunnel isolation layer.

5. The memory device of claim 1, wherein the floating gate comprises a material capable of storing electrons.

6. The memory device of claim 1, wherein the floating gate comprises at least one of titanium nitride (TiN) and tantalum nitride (TaN).

7. The memory device of claim 1, wherein the first dielectric layer comprises a material having a permittivity lower than a permittivity of each of the second and third dielectric layers.

8. The memory device of claim 1, wherein the first dielectric layer comprises a material having an energy band gap higher than an energy band gap of the second dielectric layer.

9. The memory device of claim 1, wherein the first dielectric layer comprises a silicon oxide.

10. The memory device of claim 1, wherein:
the second dielectric layer has a permittivity higher than a permittivity of the first dielectric layer and a permittivity of the third dielectric layers, and
the second dielectric layer has an energy band gap lower than an energy band gap of the first dielectric layer and lower than an energy band gap of the third dielectric layer.

11. The memory device of claim 1, wherein the second dielectric layer comprises at least one of silicon nitride, hafnium oxide, zirconium oxide, zirconium silicate, and hafnium silicate.

12. The memory device of claim 1, wherein the third dielectric layer comprises an aluminum oxide.

13. The memory device of claim 1, wherein the gate line is a select line or a word line, which is connected to a memory block.

14. The memory device of claim 1, wherein the gate line comprises a conductive layer or a semiconductor layer.

15. The memory device of claim 1, wherein the gate line comprises at least one of tungsten (W), tungsten nitride (WN), titanium nitride, molybdenum (Mo), cobalt (Co), nickel (Ni), silicon (Si), and poly-silicon (Poly-Si).

16. The memory device of claim 1, further comprising a barrier layer formed between the gate line and the third dielectric layer.

17. The memory device of claim 16, wherein the barrier layer comprises tungsten nitride (WN) or titanium nitride (TiN).

18. A method of manufacturing a memory device, the method comprising:
alternately stacking isolation layers and sacrificial layers on a lower structure;
forming a vertical hole penetrating the isolation layers and the sacrificial layers;
forming first recesses by removing portions of the sacrificial layers exposed by the vertical hole;
forming a first dielectric layer along a respective inner wall of the sacrificial layers exposed through the first recesses;
forming a floating gate inside a respective first recess in which the first dielectric layer is formed;
forming a cell plug inside the vertical hole;
forming second recesses by removing portions of the sacrificial layers to expose outer walls of the first dielectric layers;
forming a second dielectric layer on a respective outer wall of the first dielectric layers;
forming a third dielectric layer in a respective second recess along a respective outer wall of the second dielectric layers and along respective surfaces of the isolation layers; and
forming a gate line inside a respective second recess in which the third dielectric layer is formed.

19. The method of claim 18, wherein forming the first dielectric layer comprises performing a radical oxidation process.

20. The method of claim 18, wherein forming the second dielectric layer and forming the third dielectric layer comprise performing a thermal atomic layer deposition process.

21. The method of claim 18, wherein the third dielectric layer is formed to have a permittivity higher than a permittivity of the first dielectric layer.

22. The method of claim 18, wherein the floating gate is formed to include at least one of titanium nitride (TiN) and tantalum nitride (TaN).

23. The method of claim 18, wherein the first dielectric layer is formed to have an energy band gap higher than an energy band gap of the second dielectric layer.

24. The method of claim 18, wherein the first dielectric layer is formed of a silicon oxide.

25. The method of claim 18, wherein the second dielectric layer is formed of at least one of silicon nitride, hafnium oxide, zirconium oxide, zirconium silicate, and hafnium silicate.

26. The method of claim 18, wherein the third dielectric layer is formed of an aluminum oxide.

27. The method of claim 18, further comprising forming a barrier layer along an inner wall of the third dielectric layer after forming of the third dielectric layer and before forming of the gate line.
